(19) United States
(12) Patent Application Publication
(10) Pub. No.: US 2019/0136994 A1
(43) Pub. Date: May 9, 2019

(54) RELIEF VALVE AND SUBSTRATE PROCESSING APPARATUS

(71) Applicant: TOKYO ELECTRON LIMITED, Tokyo (JP)

(72) Inventors: Yuka NAKASATO, Oshu City (JP); Manabu HONMA, Oshu City (JP)

(21) Appl. No.: 16/181,467

(22) Filed: Nov. 6, 2018

(30) Foreign Application Priority Data
Nov. 7, 2017 (JP) 2017-215060

(51) Int. Cl. F16K 17/18; C23C 16/44; C23C 16/455; C23C 16/458

(52) U.S. Cl. CPC F16K 17/18; C23C 16/4412; C23C 16/4586; C23C 16/4584; C23C 16/45544

(57) ABSTRACT

A relief valve includes a first valve body having an annular shape including a peripheral edge portion, which is pressed against a hole edge portion of the communication hole, and an opening in a central portion of the annular shape; a second valve body pressed against a hole edge portion of the opening of the first valve body so as to close the opening; a first spring including a compression spring or a tension spring for pressing the first valve body against the hole edge portion of the communication hole; and a second spring including a compression spring or a tension spring for pressing the second valve body against the hole edge portion of the opening, wherein the first region and the second region communicate with each other.

### CROSS-REFERENCE TO RELATED APPLICATION

This application is based upon and claims the benefit of priority from Japanese Patent Application No. 2017-215060, filed on Nov. 7, 2017, the entire contents of which are incorporated herein by reference.

### TECHNICAL FIELD

The present disclosure relates to a relief valve and a substrate processing apparatus including the relief valve for processing a substrate in a vacuum atmosphere.

### BACKGROUND

As one of the film forming apparatuses used in a process of manufacturing a semiconductor device, an apparatus called a semi-batch type or the like which forms a film while revolving a plurality of semiconductor wafers (hereinafter referred to as “wafers”) which are substrates is known. In such a film forming apparatus, a plurality of wafers are placed in a circumferential direction on a rotary table installed in a processing container, and a film forming process is performed in a vacuum atmosphere while the wafers are being revolved by the rotation of the rotary table. A heating mechanism composed of, for example, a carbon wire heater is disposed below the rotary table, and a space between a region where the heating mechanism is disposed and a processing region where the rotary table is rotated is air-tightly partitioned by a quartz plate. As the film forming process, a method called ALD (Atomic Layer Deposition) or the like is performed by alternately and repeatedly passing a substrate through a supply region for a precursor gas and a supply region for a reaction gas reacting with the precursor gas.

An inert gas is supplied to the region where the heating mechanism is disposed, and a pressure difference between a pressure in this region and a pressure in the processing region has been adjusted to such an extent that the quartz plate is not damaged. However, when a sudden pressure fluctuation occurs in the processing container, the pressure difference becomes so large, thereby damaging the quartz plate. The semi-batch type film forming apparatus has a large internal area of the processing chamber and a large-sized quartz plate. Therefore, the quartz plate may be damaged even when the pressure difference is only, for example, about 133.3 to 166.6 Pa.

As a conventional technique, there is known a technique in which a region where a heating mechanism is disposed and an exhaust pipe for vacuum-exhausting a space where a substrate is placed are connected by a pipe, a valve is installed in the pipe, a pressure gauge for detecting the pressure of the region and a pressure gauge for detecting the pressure in the exhaust pipe are installed, and the valve is opened and closed according to a difference between pressure detection values of the respective pressure gauges.

According to this technique, although the pressure difference between the region where the heating mechanism is disposed and the processing region falls within a set value, a time delay occurs until the regions, where the exhaust pipe and the heating mechanism are disposed, communicate with each other after the valve is opened from a point of time when the pressure difference occurs. For that reason, it is not possible to follow an instantaneous differential pressure fluctuation. Accordingly, it is necessary to increase the thickness of the quartz plate to give a margin for strength. Further, a pipe for connection, a pipe heater for heating the pipe, a valve, a pressure gauge, a control board for performing pressure control, and the like are necessary, which is one of the factors that hinders the reduction in manufacturing costs, makes a structure complicated, and requires a space for arranging the structural parts.

As another conventional technique, there is known a technique in which a lid is interposed between a processing container and an operation space, and a vacuum holding valve mechanism installed in a flow path for making the interior of the processing container a vacuum region and a pressurization holding valve mechanism installed in a flow path for making the interior of the processing container a pressurization region are installed inside the lid. The vacuum holding valve mechanism and the pressurization holding valve mechanism are each formed by a combination of a diaphragm and a spring. The vacuum holding valve mechanism uses a pressure difference (about 1.033 kgf/cm²) between vacuum and atmospheric pressure to perform an opening/closing operation, and the pressurization holding valve mechanism uses a pressure difference (about 100 Torr) between pressurization and atmospheric pressure to perform an opening/closing operation. These valve mechanisms are different from the configuration of the present disclosure.

### SUMMARY

Some embodiments of the present disclosure provide a substrate processing apparatus in which a substrate is processed under a vacuum region, a processing region and another region are partitioned in a processing container via a partitioning member, and a pressure difference between the regions can instantaneously fall within a set range even when there is a pressure fluctuation between the regions. Some embodiments of the present disclosure provide a relief valve having a simple structure in which a pressure difference between a first region and a second region instantaneously falls within a set range even when there is a pressure fluctuation between the first region and the second region.

According to one embodiment of the present disclosure, there is provided a relief valve that is installed in a communication hole communicating between a first region and a second region and operates to keep a pressure difference between the first region and the second region in a predetermined range when the pressure difference exceeds a predetermined value, including: a first valve body having an annular shape including a peripheral edge portion, which is pressed against a hole edge portion of the communication hole, and an opening in a central portion of the annular shape; a second valve body pressed against a hole edge portion of the opening of the first valve body so as to close the opening; a first spring including a compression spring or a tension spring for pressing the first valve body against the hole edge portion of the communication hole; and a second spring including a compression spring or a tension spring for pressing the second valve body against the hole edge portion of the opening, wherein the first region and the second region communicate with each other by forming one of a state of opening the communication hole when the first valve body is separated from the hole edge portion of the communication hole against a restoring force of the first spring while the opening of the first valve body is being blocked by the second valve body, and a state of opening the opening when the second valve body is separated from e edge portion of the opening against a restoring force of the second spring while the first valve body is being pressed against the hole edge portion of the communication hole, in accordance with the pressure difference between the first region and the second region.

According to another embodiment of the present disclosure, there is provided a substrate processing apparatus including: a processing container configured to process a substrate in a vacuum region; an exhaust port opened into the processing container to vacuum exhaust a space in which the substrate is placed; a partitioning member provided in the processing container to partition a first region where the substrate is processed from a second region adjacent to the first region; and a relief valve described above provided between the first region and the second region.

### BRIEF DESCRIPTION OF DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is a longitudinal sectional side view of a substrate processing apparatus according to an embodiment of the present disclosure.

FIG. 2 is a cross-sectional plan view of the substrate processing apparatus.

FIG. 3 is a cross-sectional view showing a relief valve of the present disclosure installed in the substrate processing apparatus.

FIGS. 4A and 4B are perspective views showing a first valve body, a first spring, a second valve body and a second spring of the relief valve.

FIG. 5 is an explanatory view showing an operation of the relief valve.

FIG. 6 is an explanatory view showing an operation of the relief valve.

FIG. 7 is a cross-sectional view showing another example of the relief valve.

FIG. 8 is a cross-sectional view showing another application example of the relief valve.

FIG. 9 is an explanatory view showing the operation of the relief valve shown in FIG. 8.

FIGS. 10A to 10C are external views showing the appearances of a relief valve unit shown in FIG. 8 and another unit not shown in FIG. 8.

FIG. 11 is a cross-sectional view showing still another example of the relief valve.

FIG. 12 is a cross-sectional view showing still another example of the relief valve.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

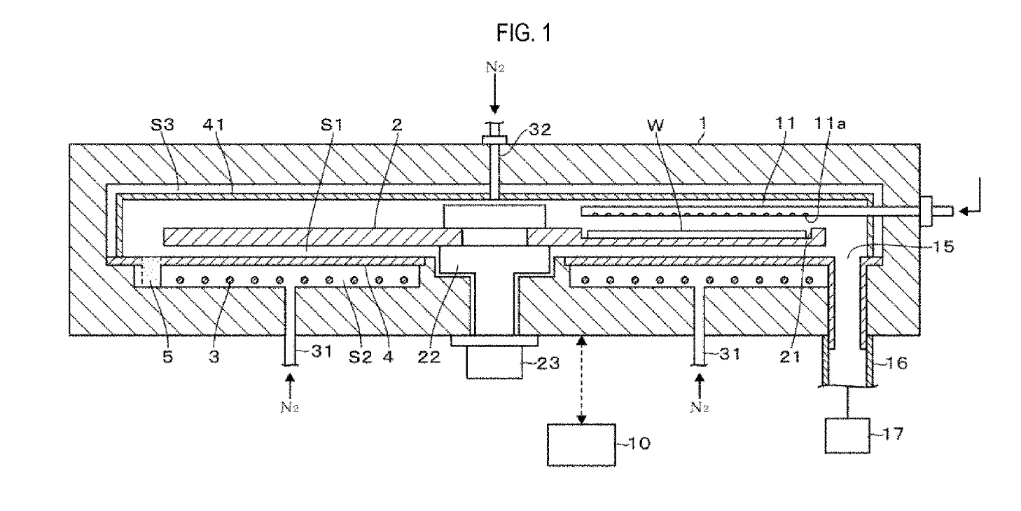

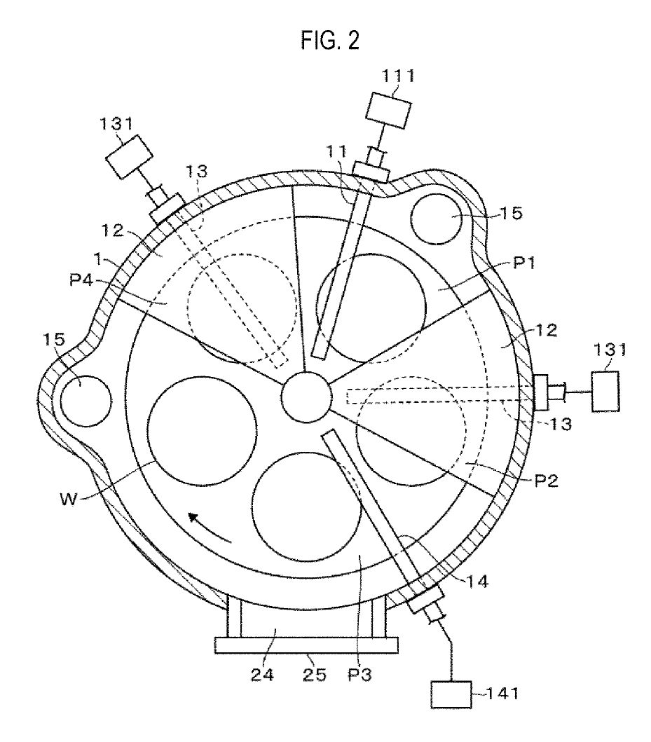

FIGS. 1 and 2 are views showing an embodiment of a vacuum processing apparatus to which a relief valve of the present disclosure is applied. The vacuum processing apparatus is a film forming apparatus using a so-called ALD (Atomic Layer Deposition) method in which a precursor gas and a reaction gas are alternately supplied onto a wafer W to form a film. The outline of the vacuum processing apparatus is as follows.

a) A plurality of wafers W, which are substrates, are placed on a rotary table 2 installed in a processing container 1, and the wafers W alternately and repeatedly pass through a precursor gas region and a reaction gas region by the rotation of the rotary table 2 to perform a film forming process.

b) A heating mechanism 3 is installed below the rotary table 2, and a quartz plate 4 is installed between the rotary table 2 and the heating mechanism 3 in order to partition a processing region S1 where the rotary table 2 is disposed and a region S2 where the heating mechanism 3 is disposed.

c) A purge gas is supplied to the region S2 where the heating mechanism 3 is disposed, and a relief valve 5 of the present disclosure is installed in the quartz plate 4 in order to suppress a pressure difference between the region S2 and the processing region S1 to fall within a predetermined range.

Next, the vacuum processing apparatus will be described in detail. The processing container 1 is configured as a vacuum container made of, for example, aluminum and formed in a substantially flat cylindrical shape. On the rotary table 2 are formed mounting parts 21, each of which is formed of a concave portion slightly larger in size than the wafers W, at equal intervals along the circumferential direction so as to mount a plurality of wafers W, for example, five wafers W, in the circumferential direction.

A rotation support part 22 is installed in the central portion of the processing container 1, and the central portion of the rotary table 2 is supported by the rotation support part 22. The rotation support part 22 is configured to be rotatable about a vertical axis by a rotation mechanism 23 including a motor, so that the rotary table 2 is rotated horizontally to revolve the wafers W.

When the region S2 where the heating mechanism 3 is disposed is referred to as a heater region S2, the heater region S2 is constituted by an annular concave, portion formed in a region corresponding to a passage region of the mounting parts 21 on the bottom surface of the processing container 1. The heating mechanism 3 is constituted by, for example, a carbon wire heater installed concentrically in the circumferential direction of the processing container 1. A downstream end of a purge gas supply path 31 to which a purge gas using an inert as such as a nitrogen gas is externally supplied is opened at, for example, two places on the lower surface of the heater region S2.

The quartz plate 4 is formed in an annular shape and is disposed above the bottom surface of the processing container 1 so as to cover the heater region S2, and the peripheral edge thereof is in contact with he inner peripheral wall of the processing container 1. The quartz plate 4 is a partitioning member for partitioning the processing region S1 and the heater region S2, and is formed to have a thickness of, for example, 10 mm. The heater region S2 has a small gap partially formed between the heater region S2 and the quartz plate 4 and maintains a predetermined pressure (degree of vacuum) so that the purge gas supplied from the purge gas supply path 31 flows to the processing region S1 side. A cover member (inner plate) 41 made of, for example, quartz is installed in the processing container 1 so as to cover the inner peripheral surface and the ceiling surface of the processing container 1. The cover member 41 is used to prevent the processing container 1 from being corroded by a processing gas. The material of the partitioning member and the cover member 41 is not limited to quartz but may be any material as long as it is corrosion-resistant to the processing gas.

As shown in FIG. 2, a precursor gas adsorption region P1, an isolation region P2, a reaction region P3 and an isolation region P4 are allocated clockwise in this order in the processing container 1. In the precursor gas adsorption region P1, a precursor gas nozzle 11 extending in the radial direction of the processing container 1 is fixed to the peripheral wall of the processing container 1. The precursor gas nozzle 11 has a plurality of gas discharge holes la arranged in the lengthwise direction so as to discharge a precursor gas to the lower side, and a portion where the gas discharge holes are arranged faces a region where the wafers W pass. The proximal end of the precursor gas nozzle 11 is connected to an external gas supply pipe via the peripheral wall of the processing container 1, and the gas supply pipe is connected to a precursor gas supply source 111 via a gas supply control device such as a valve. In FIG. 1, in order to facilitate understanding of the apparatus configuration, the precursor gas nozzle 11 is shown to overlap with an exhaust port 15 to be described later, when viewed in plan view.

In the isolation region P2, an isolation plate 12 formed of a fan-shaped plate having its lateral width gradually increasing from the central portion toward the outer peripheral side of the processing container 1 is disposed between the ceiling surface of the processing container 1 and the rotary table 2. An isolation gas nozzle 13 having isolation gas discharge holes arranged in the lengthwise direction is installed on the lower surface side of the isolation plate 12 in the same manner as the precursor gas nozzle 11. In FIG. 2, reference numeral 131 denotes an isolation gas supply source. The vertical position of the lower surface of the isolation plate 12 is lower than the upper surface of the cover member 41 in the precursor gas adsorption region P1 and the reaction region P3, so that the precursor gas and the reaction gas are prevented from being mixed with each other by supplying an isolation gas composed of an inert gas such as nitrogen gas onto the lower surface side of the isolation plate 12.

In the reaction region P3, a reaction gas nozzle 14 having reaction gas discharge holes arranged in the lengthwise direction is installed in the same manner as the precursor gas nozzle 11. The proximal end of the reaction gas nozzle 14 is connected to a reaction gas supply source 141 via a gas supply control device. The isolation region P4 is located between the precursor gas adsorption region P1 and the reaction region P3 and is configured in the same manner as the isolation region P2. Assuming that one example of a film type formed on the wafer W is a silicon oxide film, for example, a bistertiarybutylaminosilane (BTBAS) gas, which is a silicon precursor, is used as the precursor gas, and an ozone gas for generating silicon oxide by reaction with BTBAS is used as the reaction gas. A plasma generation mechanism to activate the reaction gas may be installed above the reaction region P3. The film forming process to the wafer W is performed on the upper surface side of the rotary table but in the present disclosure a region surrounded by the quartz plate 4 and the cover member that is, a region having its pressure controlled by vacuum-exhaustion through the exhaust port 15, is referred to as a “processing region” for the sake of convenience, in corresponding it with the term “heater region” partitioned by the quartz plate 4.

A purge gas supply path 32 for supplying a purge gas between the central portion of the cover member 41 and the rotation support part 22 is formed at the central portion of the ceiling portion of the processing container 1. This purge gas is used to prevent the precursor gas and the reaction gas from being mixed through a gap between the central portion of the cover member 41 and the rotation support part 22. The exhaust port 15 is formed and opened on portions of the bottom surface of the processing container 1 outside the heater region S2. The exhaust port 15 is formed by forming an opening in the quartz plate 4 and the bottom surface of the processing container 1 and fitting an exhaust sleeve into the opening. The exhaust port 15 is connected to a vacuum exhaust mechanism 17 via an exhaust path including an exhaust pipe 16. Although not shown, a pressure adjustment part for adjusting the pressure of the processing region S1 is installed in the exhaust pipe 16. In this example, the exhaust port 15 is formed at two places: a position in the precursor gas adsorption region P1 close to the isolation region P2 and a position in the reaction region P3 close to the isolation region P4.

In the peripheral portion of the processing container 1, a transport opening 24 for loading/unloading the wafer W in/from the processing container 1 by an external wafer transport mechanism is installed in a portion facing the reaction region P3. A gate valve 25 is used to open and close the transport opening 24. Below a region in the processing container 1 facing the transport opening 24, three lift pins (not shown) for supporting the wafer W are installed at positions corresponding to the stop position of the rotary table 2 at the time of delivering the wafer W. These lift pins penetrate the heater region S2, the quartz plate 4 and the mounting part 21 of the rotary table 2 from below the processing container 1, so that the wafer W is delivered from a substrate transport mechanism to the mounting part 21 by cooperating with the substrate transport mechanism. A quartz sleeve into which the lift pins are inserted is installed in the heater region S2, so that the heater region S2 and a region where the lift pins move are air-tightly partitioned.

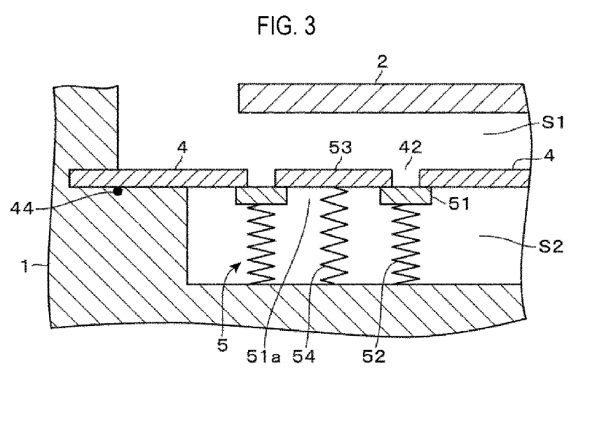

Next, the relief valve 5 of the present disclosure will he described. In FIG. 1, the relief valve 5 is indicated by hatching with a dotted line. FIG. 3 shows the detailed structure of the relief valve 5. A circular communication hole 42 communicating the processing region S1 and the heater region S2 is formed in the quartz plate 4 at a position deviated from the heating mechanism 3 toward the outer peripheral side of the processing container 1. Reference numeral 44 denotes an O ring which is a sealing material.

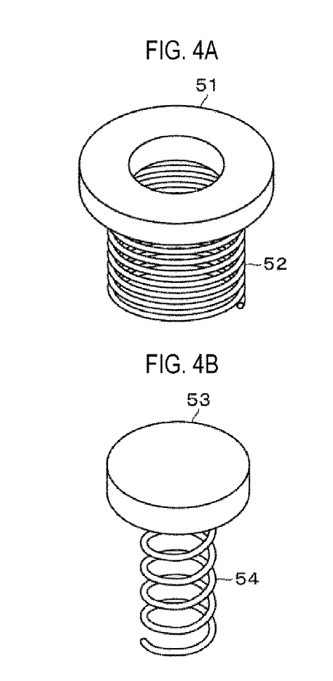

As shown in FIGS. 3 and 4A, the relief valve 5 has an annular first valve body 51. The first valve body 51 has its upper surface pressed against the lower surface of the hole edge portion of the communication hole 42 by a first spring 52 composed of a compression spring having its lower end in contact with the bottom surface of the heater region S2. In addition, as shown in FIGS. 3 and 4B, the relief valve 5 has a circular second valve body 53 having a larger diameter than an opening 51a of the first valve body 51. The second valve body 53 has its lower surface pressed against the upper surface of the hole edge portion of the opening 51a of the first valve body 51 by a second spring 54 composed of a tension spring having its lower end in contact with the bottom surface of the heater region S2. The first spring 52 is formed in a coil shape and the second spring 54 is located within a coil which is the first spring 52.

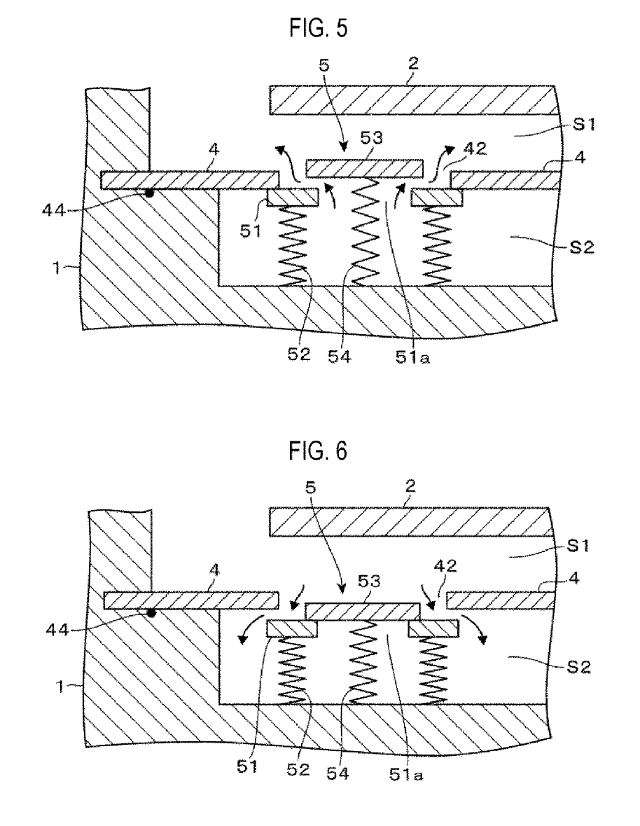

The relief valve 5 operates as follows. First, when the pressure of the heater region S2 becomes higher than the pressure of the processing region S1 by a set pressure difference or more, the second valve body 53 is pushed up against a restoring force of the second spring 54 (tension spring), as shown in FIG. 5. As a result, the communication hole 42 is opened to communicate the heater region S2 and the processing region S1. Then, an inert gas in the heater region S2 flows into the processing region S1 to decrease the pressure difference between the heater region S2 and the processing region S1. When this pressure difference becomes smaller than the set pressure difference, the second valve body 53 is pushed down by the restoring force of the second spring 54 to close the opening 51a of the first valve body 51. Therefore, the communication between the heater region S2 and the processing region S1 is blocked.

On the other hand, when the pressure of the processing region S1 becomes higher than the pressure of the heater region S2 by a set pressure difference or more, the first valve body 51 is pushed down against a restoring force of the first spring 52 (compression spring), as shown in FIG. 6. Since the second valve body 53 is biased in a way that it is pushed down by the second spring 54, it is pushed down while being pressed against the first valve body 51. As a result, the communication hole 42 is opened to communicate the heater region S2 and the processing region S1. Then, a gas in the processing region S1 flows into the heater region S2 to decrease the pressure difference between the regions S1 and S2. When this pressure difference becomes smaller than the set pressure difference, the first valve body 51 is pushed up by the restoring force of the first spring 52 to close the communication hole 42. Therefore, the communication between the processing region S1 and the heater region S2 is blocked. The set pressure difference is set to, for example, 66.6 Pa (0.5 Torr), and the spring constants of the first spring 52 and the second spring 54 are set such that the relief valve 5 is opened and closed by this pressure difference.

As shown in FIG. 1, the substrate processing apparatus is provided with a control part 10 including a computer, and a program is stored in the control part 10. This program includes a step group assembled to execute processes (which will be described later) by transmitting control signals to various parts of the film forming apparatus to control the operations of the parts. This program is installed in the control part 10 in the form of a storage medium such as a hard disk, a compact disk, a DVD, a memory card or the like.

Next, the operation of the above-described embodiment will be described. After the gate valve 25 is opened, five wafers W are sequentially delivered to the respective mounting parts (concave portions) 21 of the rotary table 2 by the external substrate transport mechanism, as described above. Next, the transport opening 24 of the processing container 1 is closed by the gate valve 25. The wafers W mounted on the mounting parts 21 are heated to, for example, 300 to 350 degrees C. by the heating mechanism 3. Then, the interior of the processing container 1 is set to a pressure of, for example, 2 torr (266.6 Pa) by the exhaust from the exhaust port 15, and the rotary table 2 is rotated clockwise at a predetermined rotation speed.

Thus, the wafers W sequentially pass through the precursor gas adsorption region P1, the isolation region P2, the reaction region P3 and the isolation region P4, and the adsorption of a precursor gas such as BTBAS in the precursor gas adsorption region P1 and the generation of a reaction product in the reaction region P3 are repeatedly performed. In this example, in the reaction region P3, the BTBAS adsorbed on the wafers W reacts with an ozone gas supplied from the reaction gas nozzle 14 to form molecular layers of silicon oxide, and the molecular layers are sequentially stacked. A nitrogen gas as an isolation gas is supplied into the isolation regions P2 and P4, and the isolation gas is flowed out from both sides of the fan-shaped isolation plate 12 in the circumferential direction, thereby preventing the precursor gas and the reaction gas from being mixed.

In addition, as described above, a purge gas is supplied to the heater region S2 and flows out to processing region S1 via a gap (not shown) so that the processing region S1 and the heater region S2 have the same pressure. Here, for example, suppose that a trouble occurs in a gas supply system or in a pressure adjustment part such as a butterfly valve installed in the exhaust pipe 16 and the pressure of the heater region S2 becomes higher than the pressure of the processing region S1 to increase a pressure difference therebetween suddenly. In this case, when the pressure difference reaches the set pressure difference of the relief valve 5, for example, 66.6 Pa, the second valve body 53 is pushed up as described above (see FIG. 5), so that the communication hole 42 is opened to allow a gas to flow from the heater region S2 into the processing region S1, thereby making the pressures of the regions S1 and S2 aligned. Conversely, suppose that the pressure of the processing region S1 becomes higher than the pressure of the heater region S2 to increase a pressure difference therebetween suddenly. In this case, as described above (see FIG. 6), while the second valve body 53 is being pressed against the first valve body 51, the first valve body 51 is pushed down so that the communication hole 42 is opened to allow a gas to flow from the processing region S1 into the heater region S2, thereby making the pressures of the regions S2 and S1 aligned.

According to the above-described embodiment, in the structure in which the space between the processing region S1 and the heater region S2 is partitioned by the quartz plate 4, since the relief valve 5 is installed and is instantaneously opened even when a sudden pressure fluctuation occurs in one of the regions S1 and S2, no large pressure difference occurs between the regions S1 and S2. Therefore, since no high pressure is applied to the quartz plate 4, damage to the quartz plate 4 can be avoided. As the quartz plate 4 has a large area and is easily broken by a small pressure difference, the structure of this embodiment can be used effectively. From another viewpoint, since the quartz plate 4 having strength enough to withstand the set pressure difference at which relief valve 5 operates can be used, there is no need to consider a large margin for strength.

Then, the annular first valve body 51 and the second valve body 53 pressed so as to close the opening of the first valve body 51 are combined with the compression spring 52 and the tension spring 54, thereby, so to speak, constituting a bidirectional relief valve 5. Therefore, it is possible to secure a relief function with a simpler structure than a structure using a dedicated one-way relief valve for flowing a gas from the processing region S1 to the heater region S2 and a dedicated one-way relief valve for flowing a gas from the heater region S2 to the processing region S1. In addition, by using such a relief valve 5, as compared with a case where the heater region S2 and the exhaust pipe 16 are connected by a pipe provided with a valve, expensive parts including a pressure gauge and the like are not required, which contributes to lowering the manufacturing costs and avoiding complication of the apparatus configuration. Further, since the first and second springs 52 and 54 of the relief valve 5 are installed in the heater region S2, corrosion of the first and second springs 52 and 54 can be advantageously prevented even when the processing region S1 is in a corrosion atmosphere.

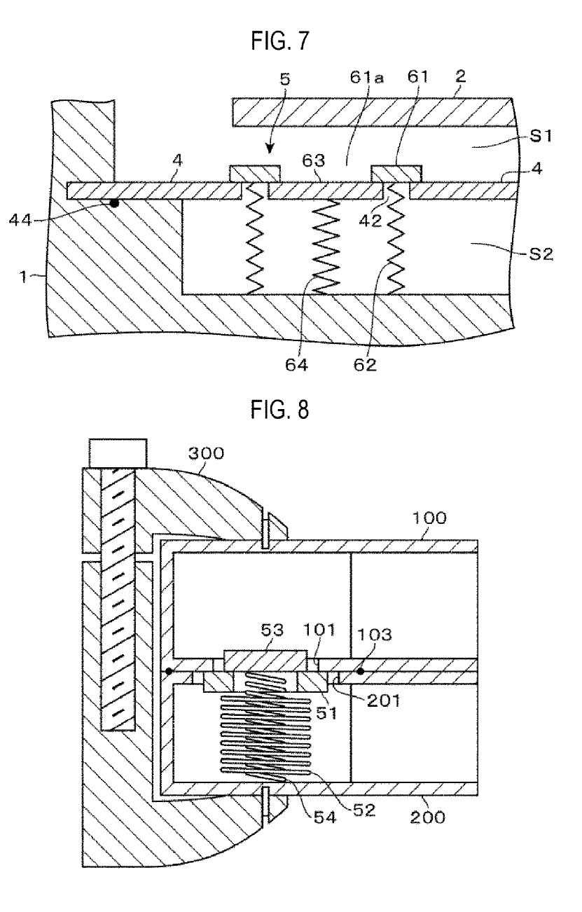

The relief valve 5 is not limited to the structure shown in FIG. 3, but may have, for example, a structure shown in FIG. 7. In FIG. 7, reference numeral 61 denotes an annular first valve body, reference numeral 62 denotes a first spring composed of a tension spring, reference numeral 63 denotes a circular second valve body, and reference numeral 64 denotes a second spring composed of a compression spring. The first valve body 61 has its lower surface pressed against the upper surface of the hole edge portion of the communication hole 42 by the first spring 62 composed of a tension spring having its lower end in contact with the bottom surface of the heater region S2. The second valve body 63 has its upper surface pressed against the lower surface of the hole edge portion of an opening 61a of the first valve body 61 by the second spring 64 composed of a compression spring having its lower end in contact with the bottom surface of the heater region S2.

In the structure shown in FIG. 7, when the pressure of the heater region S2 becomes higher than the pressure of the processing region S1 by a set pressure difference or more, the first valve body 61 is pushed up against the restoring force of the first spring 62 to open the communication hole 42. Conversely, when the pressure of the processing region S1 becomes higher than the pressure of the heater region S2 by a set pressure difference or more, the second valve body 63 is pushed down against the restoring force of the second spring 64 to open the communication hole 42. That is, the example of FIG. 7 where the vertical arrangement of the first valve body 51 and the second valve body 53 in the example of FIG. 3 is reversed and the arrangement of the tension spring and the compression spring is reversed has the same function as the example of FIG. 3.

The relief valve 5 may be installed between the processing region S1 and a region S3 between the cover member 41 and the inner wall of the processing container 1, for example, on the cover member 41. Since the cover member 41 is placed in the processing container 1 without being fixed by screws or the like, positional deviation may occur when there occurs a large pressure difference between the regions S2 and S3. Therefore, it is effective to install the relief valve 5 between the regions S2 and S3.

Examples of the portions to which the relief valve 5 can be applied are as follows. There is known an apparatus in which a substrate such as a wafer is placed in a processing container for forming a vacuum atmosphere and is heated by a heating lamp or irradiated with an ultraviolet ray by an ultraviolet lamp. In a case where these lamps are placed in a vacuum atmosphere and a quartz plate is interposed between the vacuum atmosphere and a processing atmosphere in which the substrate is placed, when the relief valve 5 is installed in the quartz plate, damage to the quartz plate can be avoided. Further, the relief valve 5 can be applied not only to a semiconductor manufacturing apparatus but also to, for example, a pharmaceutical product manufacturing factory. In a factory that manufactures pellets as pharmaceutical products from powder materials, a powder materials weighing room, a powder materials mixing room, a mixed material molding room and the like are partitioned from each other and are arranged along a transport region by a transport robot, a door is installed between the transport region and each processing room, and the processing rooms are set to a positive pressure. In such a factory, when the relief valve 5 is installed between the transport region and each processing room, the door can be opened and closed without hindrance even when a transient trouble occurs in a gas supply system or the like and a large pressure difference occurs between two different atmospheres.

FIG. 8 is a view showing another application example of the relief valve of the present disclosure, and its appearance is shown in FIG. 10A. Reference numeral 100 denotes a first flow path member, and reference numeral 200 denotes a second flow path member. The flow path members 100 and 200 each have a structure in which a cylindrical portion and a rectangular portion are connected in series, and the cylindrical portion of the flow path member 100 and the cylindrical portion of the flow path member 200 are stacked and are supported by a frame body 300 so as to be rotatable about the center of the cylindrical portions as a rotation center. The flow path members 100 and 200, the frame body 300 and the relief valve constitute a valve unit. This valve unit may be handled as a relief valve, in which case the relief valve is constituted by a relief valve body and the flow path members.

An opening 101 is formed in the bottom of the cylindrical portion of the flow path member 100 and an opening 201 larger than the opening 101 is formed in the ceiling portion of the cylindrical portion of the flow path member 200. Both the openings 101 and 201 overlap concentrically with each other. Reference numeral 103 denotes an O-ring which is a sealing material. The flow path members 100 and 200 can rotate with each other while maintaining airtightness by the O-ring 103. The opening 101 and the opening 201 correspond to a communication hole communicating the flow path members 100 and 200, and a relief valve is installed so as to open and close the communication hole. This relief valve is denoted by the same reference numeral as that used for the relief valve shown in FIG. 3.

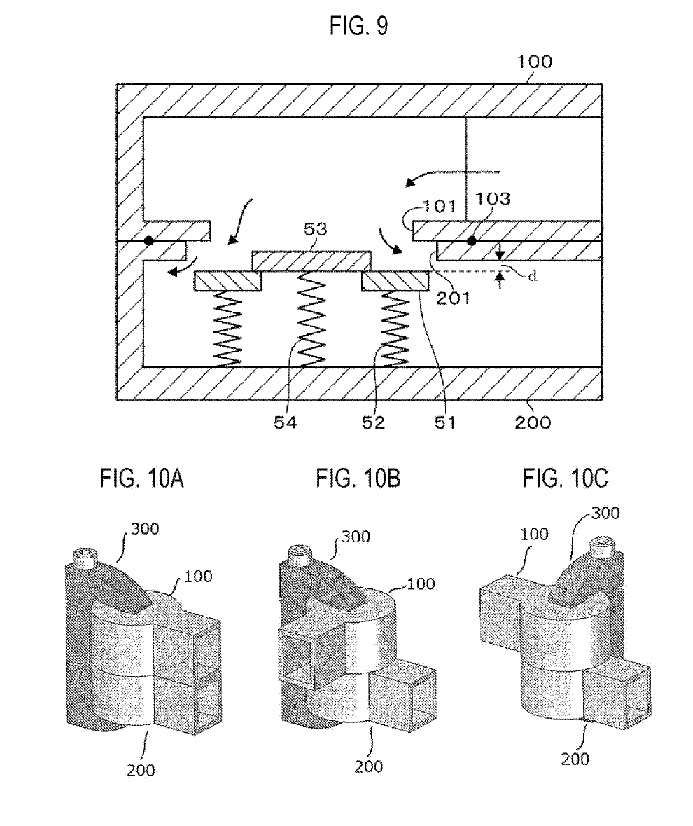

Since the stacked body of the bottom of the cylindrical portion of the flow path member 100 and the ceiling portion of the cylindrical portion of the flow path member 200 corresponds to the quartz plate 4 of FIG. 3, the structure and operation thereof are the same as those of the relief valve 5 and description thereof will not be repeated. FIG. 9 shows an operation when he relief valve 5 in the valve unit shown in FIG. 8 is opened. In this example, an operation when the pressure in the first flow path member 100 is higher by more than a set pressure difference than the pressure in the second flow path member 200. In this case, when the lower first valve body 51 is pushed down, the upper surface of the first valve body 51 is located at a distance d (see FIG. 9) from the lower surface of the ceiling portion of the second flow path member 200.

Therefore, a state is formed in which a gap formed when he first valve body 51 moves away from the hole edge portion of the communication hole can be seen from a position horizontally away from the relief valve 5 in the flow path member 200. In other words, the flow path of the second flow path member 200 extends in a direction perpendicular to the movement direction of the first valve body 51 when the first valve body 51 is separated from the hole edge portion of the communication hole. Further, even when the pressure in the second flow path member 200 is higher by more than the set pressure difference than the pressure in the first flow path member 100 to push up the second valve body 53, the lower surface of the second valve body 53 becomes higher than the upper surface of the bottom of the first flow path member 100. Therefore, the flow path of the first flow path member 100 extends in a direction perpendicular to the movement direction of the second valve body 53 when the second valve body 53 is separated from the first valve body 51. With such a structure, since the degree of hindrance of the way is small when seeing the relief valve 5 from a gas flowing in the flow path in each of the flow path members 100 and 200, in other words, since the conductance can be large, the pressure difference can be relaxed more quickly.

FIG. 10B shows a structure in which the first flow path member 100 and the second flow path member 200 are shifted from each other by 90 degrees. FIG. 10C shows a structure in which the first flow path member 100 and the second flow path member 200 extend in the opposite direction. In the example shown in FIGS. 10A to 10C, each of the flow path members 100 and 200 has a structure in which a cylindrical portion and a rectangular portion are connected in series, but may have a structure in which a cylindrical portion and another cylindrical portion are connected in series or a rectangular portion and another rectangular portion are connected in series.

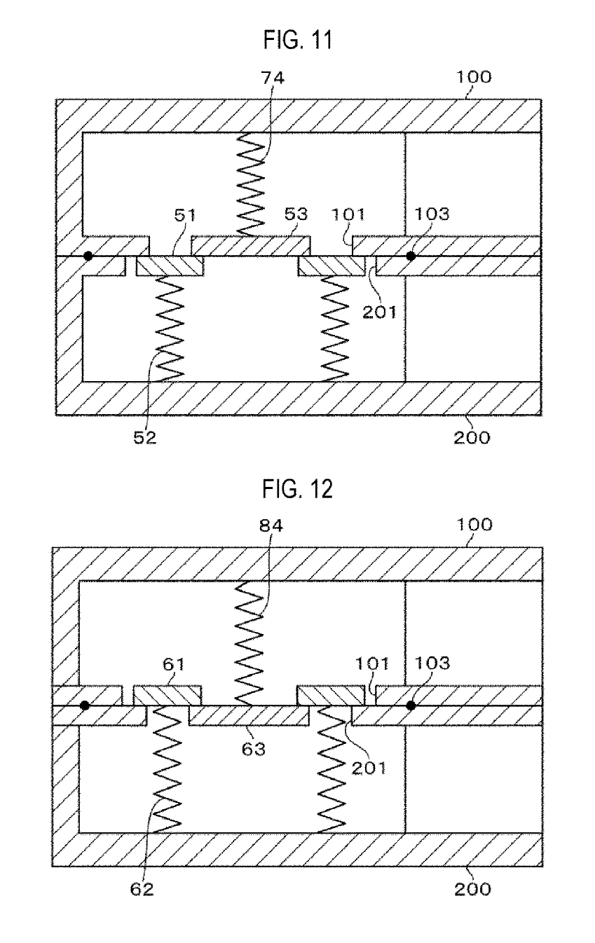

Next, another structural example of the relief valve 5 will be described with the above-described structure example in which the relief valve 5 of the present disclosure is interposed between the first flow path member 100 and the second flow path member 200, with reference to FIGS. 11 and 12. A relief valve 5 shown in FIG. 11 uses a compression spring (denoted by reference numeral 74) installed in the first flow path member 100, as the second spring for pressing the second valve body 53 against the first valve body 51 in the relief valve 5 shown in FIG. 3. Further, a relief valve 5 shown in FIG. 12 uses a tension spring (denoted by reference numeral 84) installed in the first flow path member 100, as the second spring for pressing the second valve body 63 against the first valve body 61 in the relief valve 5 shown in FIG. 7. The relief valves 5 shown in FIGS. 11 and 12 also have the same operation and effects as the relief valve 5 described above.

According to the present disclosure in some embodiments, a relief valve that is installed in a communication hole communicating a first region and a second region includes an annular first valve body and a second valve body which is pressed so as to close an opening of the first valve body. When a pressure difference between the first region and the second region is equal to or smaller than a predetermined value, the communication hole is closed in a state where the first valve body is integrated with the second valve body. When the pressure difference exceeds the predetermined value, one of a state where the communication hole is opened while the first valve body is integrated with the second valve body and a state where the first valve body is separated from the second valve body is formed according to the pressure magnitude relationship between the first region and the second region. These states can be formed by combining one of a tension spring and a compression spring with the first valve body and the second valve body. Accordingly, since a relief valve for one way and a relief valve for the opposite way are not separately installed and a two-way relief function is provided for the common valve, the two-way relief function an he achieved by a simplified structure.

Further, by applying the above-described relief valve to a substrate processing apparatus in which a substrate is processed under a vacuum region and in which a processing region and another region are partitioned in a processing container via a partitioning member, a pressure difference between the regions can instantaneously fall within a set range even when a pressure fluctuation occurs between the regions. Therefore, it s possible to set the strength margin of the partition member to be lower and it is possible to simplify the structure such as eliminating a need for a pressure gauge or the like.

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A relief valve that is installed in a communication hole communicating between a first region and a second region and operates to keep a pressure difference between the first region and the second region in a predetermined range when the pressure difference exceeds a predetermined value, comprising:
a first valve body having an annular shape including a peripheral edge portion, which is pressed against a hole edge portion of the communication hole, and an opening in a central portion of the annular shape;
a second valve body pressed against a hole edge portion of the opening of the first valve body so as to close the opening;
a first spring including a compression spring or a tension spring for pressing the first valve body against the hole edge portion of the communication hole; and
a second spring ding a compression spring or a tension spring for pressing the second valve body against the hole edge portion of the opening,
wherein the first region and the second region communicate with each other by forming one of a state of opening the communication hole when the first valve body is separated from the hole edge portion of the communication hole against a restoring force of the first spring the opening of the first valve body is being blocked by the second valve body, and a state of opening the opening when the second valve body is separated from the hole edge portion of the opening against a restoring force of the second spring while the first valve body is being pressed against the hole edge portion of the communication hole, in accordance with the pressure difference bet the first region and the second region.

2. The relief valve of claim 1, wherein a one side flow path corresponding to the first region and extending in a direction perpendicular to the movement direction of the first valve body through a gap formed when the first valve body is separated from the hole edge portion of the communication hole, and the other side flow path corresponding to the second region and extending in a direction perpendicular to the movement direction of the second valve body through a gap formed when the second valve body is separated from the first valve body, are formed.

3. A substrate processing apparatus comprising:
a processing container configured to process a substrate in a vacuum region;
an exhaust port opened into the processing container to vacuum-exhaust a space in which the substrate is placed;
a partitioning member provided in the processing container to partition a first region where the substrate is processed from a second region adjacent to the first region; and
a relief valve of claim 1 provided between the first region and the second region.

4. The substrate processing apparatus of claim 3, wherein the second region is a region in which a heating mechanism for heating the substrate is disposed.

5. The substrate processing apparatus of claim 3, further comprising:
a revolution mechanism configured to revolve a plurality of substrates mounted respectively on mounting parts to pass the plurality of substrates through the processing regions; and
a processing gas supply part configured to supply a processing gas to the processing regions,
wherein the second region is located below a revolution orbit of the substrate via the partitioning member.

6. The substrate processing apparatus of claim 3, wherein the first spring and the second spring are disposed in the second region.
